(19) United States
(12) Patent Application Publication
(10) Pub. No.: US 2025/0364783 A1
(43) Pub. Date: Nov. 27, 2025

(54) WAVELENGTH VARIABLE LIGHT SOURCE

(71) Applicant: NEC Corporation, Tokyo (JP)

(72) Inventor: Naoki KOBAYASHI, Tokyo (JP)

(73) Assignee: NEC Corporation, Tokyo (JP)

(21) Appl. No.: 19/203,494

(22) Filed: May 9, 2025

(30) Foreign Application Priority Data
May 22, 2024 (JP) 2024-083107

(51) Int. Cl. H01S 5/0687; H01S 5/04

(52) U.S. Cl. CPC H01S 5/0687; H01S 5/041

(57) ABSTRACT

A wavelength variable light source includes: a first substrate on which a gain chip and an optical amplifier are formed, the gain chip including a first optical waveguide and the optical amplifier including a second optical waveguide; and a second substrate on which a wavelength variable block, a third optical waveguide, and a fourth optical waveguide are formed, the wavelength variable block including a wavelength variable element, the third optical waveguide being connected to an input end of the wavelength variable block, and the fourth optical waveguide being connected to an output end of the wavelength variable block, in which the first optical waveguide and the third optical waveguide are optically coupled to each other and the second optical waveguide and the fourth optical waveguide are optically coupled to each other by mounting the first substrate on the second substrate.

### INCORPORATION BY REFERENCE

This application is based upon and claims the benefit of priority from Japanese patent application No. 2024-083107, filed on May 22, 2024, the disclosure of which is incorporated herein in its entirety by reference.

### TECHNICAL FIELD

The present disclosure relates to a wavelength variable light source.

### BACKGROUND ART

As related art, Japanese Unexamined Patent Application Publication No. 2019-197837 discloses a multi-wavelength light source. The multi-wavelength light source disclosed in Japanese Unexamined Patent Application Publication No. 2019-197837 includes a laser, an optical amplifier, an optical demultiplexer, and output waveguides. The laser includes a laser gain medium and a plurality of diffraction gratings. The optical amplifier collectively amplifies a multi-wavelength laser beam output from the laser. The optical demultiplexer demultiplexes a laser beam output from the optical amplifier. The output waveguides are connected to the optical demultiplexer and output light beams with the multiple wavelengths.

According to Japanese Unexamined Patent Application Publication No. 2019-197837, the laser gain medium and the optical amplifier are formed in the same substrate and separated from each other by a separation groove. The plurality of diffraction gratings, the optical demultiplexer, and the output waveguides are formed in a silicon photonics substrate. A groove or a recess is formed in the silicon photonics substrate. A substrate in which the laser gain medium and the optical amplifier are formed is mounted on the silicon photonics substrate so that it is accommodated in the groove or the recess formed in the silicon photonics substrate.

### SUMMARY

In recent years, in a wavelength variable light source including a light source and a wavelength selective filter, a structure in which a Silicon photonics (SiP) element on which a wavelength selective filter is mounted is optically coupled to a gain chip, which is the light source, has been used. Further, a Semiconductor Optical Amplifier (SOA) is often coupled to an end face of the SiP element in order to make the wavelength variable light source have a function of adjusting its light output. In the above wavelength variable light source, light output from the gain chip is input to the wavelength selective filter, and the light output from the wavelength selective filter is input to the SOA.

The light source disclosed in Japanese Unexamined Patent Application Publication No. 2019-197837 is a multi-wavelength light source, and a light beam output from the laser is input to the optical amplifier as it is in the same substrate. According to Japanese Unexamined Patent Application Publication No. 2019-197837, the gain chip cannot selectively input a light beam having a desired wavelength to the optical amplifier, and the optical amplifier amplifies a laser beam of multi-wavelengths collectively. In general, in a wavelength variable light source, a gain chip and a semiconductor optical amplifier are formed on separate substrates and are individually connected to a wavelength variable block. In this case, it is necessary to individually mount a substrate on which the gain chip is formed and a substrate on which the semiconductor optical amplifier is formed on a silicon photonics substrate. Therefore, there is a problem that it takes time to perform a mounting operation and hence the productivity is low.

One of the illustrative objects of the present disclosure is to provide a wavelength variable light source that shortens the time required to perform a mounting operation.

A wavelength variable light source according to one example aspect of the present disclosure includes: a first substrate on which a gain chip and an optical amplifier are formed, the gain chip including a first optical waveguide and the optical amplifier including a second optical waveguide; and a second substrate on which a wavelength variable block, a third optical waveguide, and a fourth optical waveguide are formed, the wavelength variable block including a wavelength variable element, the third optical waveguide being connected to an input end of the wavelength variable block, and the fourth optical waveguide being connected to an output end of the wavelength variable block. In the wavelength variable light source, the first optical waveguide and the third optical waveguide are optically coupled to each other and the second optical waveguide and the fourth optical waveguide are optically coupled to each other by mounting the first substrate on the second substrate.

One illustrative advantage of the above-described example embodiment is that the time required to perform a mounting operation can be shortened.

### BRIEF DESCRIPTION OF DRAWINGS

The above and other aspects, features and advantages of the present disclosure will become more apparent from the following description of certain example embodiments when taken in conjunction with the accompanying drawings, in which:

FIG. 1 is a layout diagram showing an example of a configuration of a first wavelength variable light source according to the present disclosure; and

FIG. 2 is a layout diagram showing an example of a configuration of a second wavelength variable light source according to the present disclosure.

### EXAMPLE EMBODIMENT

The example embodiments according to the present disclosure will be described hereinafter in detail with reference to the drawings. Note that, in order to clarify the description, the following descriptions and the drawings are partially omitted and simplified as appropriate. Further, the same elements and similar elements are denoted by the same reference symbols throughout the drawings, and redundant descriptions are omitted as necessary.

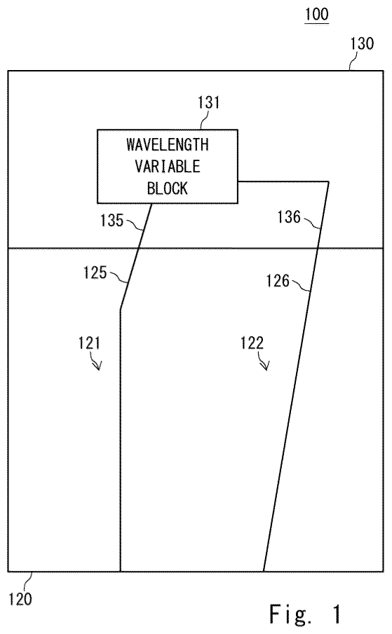

A first example embodiment will be described. FIG. 1 is a layout diagram showing an example of a configuration of a first wavelength variable light source according to the present disclosure. A wavelength variable light source 100 shown in FIG. 1 includes a first substrate 120 and a second substrate 130. In the wavelength variable light source 100, the first substrate 120 is mounted on the second substrate 130. In the following description, a side face of the first substrate 120 adjacent to the second substrate 130 is referred to as a first end face. Further, a side face of the second substrate 130 adjacent to the first substrate 120 is referred to as a second end face.

The first substrate 120 includes a gain chip 121, which is a light source, and an optical amplifier 122. The first substrate is also referred to as an optical semiconductor substrate. The gain chip 121 is an element used as an optical gain medium of an external resonator type laser. The gain chip 121 includes a first optical waveguide 125. The optical amplifier 122 is a semiconductor optical amplifier, which is a device that amplifies a laser light. The optical amplifier 122 includes a second optical waveguide 126. The optical amplifier 122 is used to adjust a light output of the wavelength variable light source 100. In the first substrate 120, both the first optical waveguide 125 and the second optical waveguide 126 are formed so that they extend from the first end face to an end face opposite to the first end face.

The second substrate 130 is, for example, a Silicon on Insulator (SOI) substrate, which is a silicon photonics substrate on which optical waveguides and an optical element are formed by silicon wire waveguides. The second substrate 130 is also referred to as an optical integrated circuit or an optical integrated element. The second substrate 130 includes a wavelength variable block 131, a third optical waveguide 135, and a fourth optical waveguide 136. The wavelength variable block 131 includes, for example, a wavelength selective filter or a wavelength selective element such as a diffraction grating. The third optical waveguide 135 is formed so that it extends from the second end face of the second substrate 130 to an input end of the wavelength variable block 131. The fourth optical waveguide 136 is formed so that it extends from the second end face of the second substrate 130 to an output end of the wavelength variable block 131.

Both the first optical waveguide 125 and the second optical waveguide 126 extend to the first end face of the first substrate 120. Further, both the third optical waveguide 135 and the fourth optical waveguide 136 extend to the second end face of the second substrate 130. The first optical waveguide 125 and the second optical waveguide 126 are exposed at the first end face, and the third optical waveguide 135 and the fourth optical waveguide 136 are exposed at the second end face. In a mounting operation, the first substrate 120 is mounted on the second substrate 130 so that the first end face and the second end face are joined to each other. As a result, the first optical waveguide 125 and the second optical waveguide 126 of the first substrate 120 are optically coupled to the third optical waveguide 135 and the fourth optical waveguide 136 of the second substrate 130, respectively.

It is assumed that the height, the position, and the size of the first optical waveguide 125 at the first end face respectively coincide with the height, the position, and the size of the third optical waveguide 135 at the second end face. It is also assumed that the height, the position, and the size of the first end face of the second optical waveguide 126 respectively coincide with the height, the position, and the size of the second end face of the fourth optical waveguide 136. The first substrate 120 is mounted on the second substrate 130, whereby the first optical waveguide 125 on the first substrate 120 is optically coupled to the third optical waveguide 135 on the second substrate 130 by end face coupling. Further, the second optical waveguide 126 on the first substrate 120 is optically coupled to the fourth optical waveguide 136 on the second substrate 130 by end face coupling.

In the gain chip 121, a reflective coating is applied to the end face of the first optical waveguide 125 opposite to the first end face. Light output from the gain chip 121 is input from the first optical waveguide 125 to the third optical waveguide 135, and is input through the third optical waveguide 135 to the wavelength variable block 131. Light output from the wavelength variable block 131, i.e., a laser light, is input from the fourth optical waveguide 136 to the second optical waveguide 126, and is amplified by the optical amplifier 122. The wavelength variable light source 100 outputs the amplified laser light from the end face of the second optical waveguide 126 opposite to the first end face. The amplification factor in the optical amplifier 122 is adjusted so that a desired light output can be obtained.

In this example embodiment, light output from the gain chip 121 is input to the wavelength variable block 131, and light output from the wavelength variable block 131 is input to the optical amplifier 122. In a mounting operation, the first optical waveguide 125 and the second optical waveguide 126 formed on the first substrate 120 are optically coupled to the third optical waveguide 135 and the fourth optical waveguide 136, respectively. As a result, the gain chip 121 and the optical amplifier 122 formed on the first substrate 120 are connected to each other through the wavelength variable block 131 formed on the second substrate 130. In this example embodiment, the optical amplifier 122 amplifies light of a wavelength selected in the wavelength variable block 131.

It is assumed here that a case is one in which the gain chip 121 and the optical amplifier 122 are formed on separate substrates. In this case, two optical semiconductor substrates need to be individually mounted on the second substrate 130 which is a silicon photonics substrate. That is, it is necessary to mount an element on a silicon photonics substrate twice. Therefore, it takes time to perform a mounting operation. In this example embodiment, the gain chip 121 and the optical amplifier 122 are formed on the same substrate. This makes it possible to obtain a wavelength variable light source in which a light output can be adjusted by performing a mounting operation only once. Therefore, as compared to a case in which the gain chip 121 and the optical amplifier 122 are formed on separate substrates, the time required to perform a mounting operation can be shortened and hence the productivity can be improved.

In this example embodiment, by joining the first end face of the first substrate 120 and the second end face of the second substrate 130 to each other, the first optical waveguide 125 and the second optical waveguide 126 are optically coupled to the third optical waveguide 135 and the fourth optical waveguide 136, respectively. In this example embodiment, since the first substrate 120 is mounted on the second substrate 130 at one side face, a mounting operation can be performed more easily than in a case where the first substrate 120 is mounted on the second substrate 130 at two or more side faces.

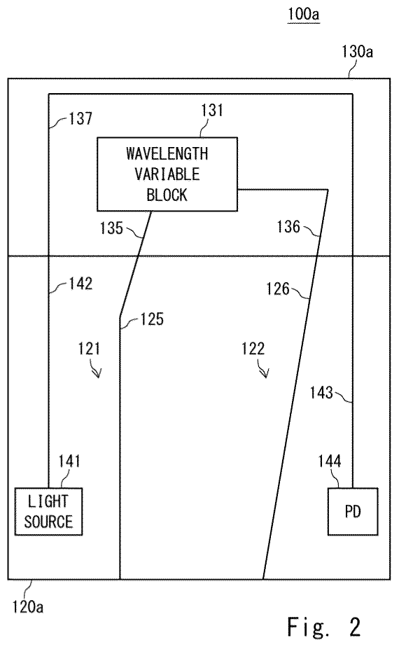

Next, a second example embodiment will be described. FIG. 2 is a layout diagram showing an example of a configuration of a second wavelength variable light source according to the present disclosure. In a wavelength variable light source 100a shown in FIG. 2, a first substrate 120a includes a light source 141, a fifth optical waveguide 142, a sixth optical waveguide 143, and a Photo Detector (PD) 144 in addition to the components of the first substrate 120 in the wavelength variable light source 100 shown in FIG. 1. Furter, a second substrate 130a includes a seventh optical waveguide 137 in addition to the components of the second substrate 130 in the wavelength variable light source 100 shown in FIG. 1.

The light source 141 outputs a laser light of a predetermined wavelength. A semiconductor laser such as a Distributed feedback laser diode (DFB) laser or a Fabry-perot (FP) laser can be used as the light source 141. The photo detector 144 detects light to be input. The photo detector 144 includes, for example, an SOA, and the SOA is used as a photo detector. The light source 141 and the photo detector 144 are formed in an area of the first substrate 120a outside an area thereof where the gain chip 121 and the optical amplifier 122 are formed. The fifth optical waveguide 142 is connected to the light source 141. The sixth optical waveguide 143 is connected to the photo detector 144. Both the fifth optical waveguide 142 and the sixth optical waveguide 143 extend to the first end face of the first substrate 120a and are exposed at the first end face.

The seventh optical waveguide 137 extends from one position on a second end face of the second substrate 130a to another position on the second end face thereof. In a case where the first substrate 120a is mounted on the second substrate 130a, one end of the seventh optical waveguide 137 is connected to the fifth optical waveguide 142, and the other end thereof is connected to the sixth optical waveguide 143. The seventh optical waveguide 137 is formed in an area of the second substrate 130a outside an area thereof where the wavelength variable block 131 is formed. For example, as shown in FIG. 2, the seventh optical waveguide 137 is formed so that it extends along an outer edge of the second substrate 130a.

The light source 141 is lighted in response to performing an operation of mounting the first substrate 120a on the second substrate 130a. In a case where the first substrate 120a is mounted on the second substrate 130a, the fifth optical waveguide 142 connected to the light source 141 is optically coupled to one end side of the seventh optical waveguide 137 formed in the second substrate 130a by end face coupling. Further, the sixth optical waveguide 143 connected to the photo detector 144 is optically coupled to the other end side of the seventh optical waveguide 137 formed in the second substrate 130a by end face coupling.

Light output from the light source 141 is input from the fifth optical waveguide 142 to the seventh optical waveguide 137 formed in the second substrate 130a at a boundary between the first substrate 120a and the second substrate 130a. The light input to the seventh optical waveguide 137 is input to the sixth optical waveguide 143 to which the photo detector 144 is connected. The photo detector 144 detects the light input from the sixth optical waveguide 143. During a mounting operation, a relative positional relationship between the first substrate 120a and the second substrate 130a is adjusted while monitoring the amount of light detected by the photo detector 144. A position where the first substrate 120a is mounted is adjusted so that, for example, the magnitude of current flowing through the semiconductor optical amplifier used as the photo detector 144 becomes maximum. In other words, a position where the first substrate 120a is mounted is adjusted so that the amount of light received by the photo detector 144 becomes maximum.

In general, in a case where the gain chip is mounted on the SiP substrate, it is necessary to control the characteristic of an optical element of a SiP substrate in order to perform accurate alignment. For example, in a mounting operation, a position where the gain chip is mounted is adjusted while monitoring a light output wavelength of the wavelength variable block or an intensity of the output light, and then the gain chip is mounted on the SiP substrate at a position where an optimal characteristic thereof is obtained. In this case, it takes time to control an optical characteristic of the SiP element, which deteriorates the productivity.

In contrast to the above, in this example embodiment, a mounting operation can be performed based on the amount of light received by the photo detector 144 formed on the first substrate 120a. For example, the first substrate 120a is mounted on the second substrate 130a so that the amount of light received by the photo detector 144 becomes maximum. In this example embodiment, in a mounting operation, there is no need to control the elements on the second substrate 130a. Therefore, in this example embodiment, the first substrate 120a can be mounted on the second substrate 130a without deteriorating the productivity.

While the present disclosure has been particularly shown and described with reference to example embodiments thereof, the present disclosure is not limited to these example embodiments. It will be understood by those of ordinary skill in the art that various changes in form and details may be made therein without departing from the spirit and scope of the present disclosure as defined by the claims. And each example embodiment can be appropriately combined with at least one of example embodiments.

Each of the drawings or figures is merely an example to illustrate one or more example embodiments. Each figure may not be associated with only one particular example embodiment, but may be associated with one or more other example embodiments. As those of ordinary skill in the art will understand, various features or steps described with reference to any one of the figures can be combined with features or steps illustrated in one or more other figures, for example, to produce example embodiments that are not explicitly illustrated or described. Not all of the features or steps illustrated in any one of the figures to describe an example embodiment are necessarily essential, and some features or steps may be omitted. The order of the steps described in any of the figures may be changed as appropriate.

The whole or part of the example embodiments disclosed above can be described as, but not limited to, the following supplementary notes.

### Supplementary Note 1

A wavelength variable light source comprising:
a first substrate on which a gain chip and an optical amplifier are formed, the gain chip including a first optical waveguide and the optical amplifier including a second optical waveguide; and
a second substrate on which a wavelength variable block, a third optical waveguide, and a fourth optical waveguide are formed, the wavelength variable block comprising a wavelength variable element, the third optical waveguide being connected to an input end of the wavelength variable block, and the fourth optical waveguide being connected to an output end of the wavelength variable block,
wherein the first optical waveguide and the third optical waveguide are optically coupled to each other and the second optical waveguide and the fourth optical waveguide are optically coupled to each other by mounting the first substrate on the second substrate.

### Supplementary Note 2

The wavelength variable light source according to supplementary note 1, wherein
both the first optical waveguide and the second optical waveguide extend to a first end face of the first substrate, and both the third optical waveguide and the fourth optical waveguide extend to a second end face of the second substrate, and
the first substrate is mounted on the second substrate by joining the first end face and the second end face to each other.

### Supplementary Note 3

The wavelength variable light source according to supplementary note 1 or 2, wherein the first optical waveguide and the second optical waveguide are optically coupled to the third optical waveguide and the fourth optical waveguide, respectively, by end face coupling.

### Supplementary Note 4

The wavelength variable light source according to any one of supplementary notes 1 to 3, wherein the first substrate is an optical semiconductor substrate, and the second substrate is a silicon photonics substrate.

### Supplementary Note 5

The wavelength variable light source according to any one of supplementary notes 1 to 4, wherein
the first substrate further comprises s a light source, a fifth optical waveguide connected to the light source, a photo detector, and a sixth optical waveguide connected to the photo detector, and
the second substrate comprises a seventh optical waveguide, one end of the seventh optical waveguide being connected to the fifth optical waveguide and another end of the seventh optical waveguide being connected to the sixth optical waveguide in a case where the first substrate is mounted on the second substrate.

### Supplementary Note 6

The wavelength variable light source according to supplementary note 5, wherein the seventh optical waveguide is formed in an area of the second substrate outside an area thereof where the wavelength variable block is formed.

### Supplementary Note 7

The wavelength variable light source according to supplementary note 5 or 6, wherein the light source comprises a semiconductor laser.

### Supplementary Note 8

The wavelength variable light source according to any one of supplementary notes 5 to 7, wherein the photo detector comprises a semiconductor optical amplifier.

### Supplementary Note 9

The wavelength variable light source according to any one of supplementary notes 5 to 8, wherein the first substrate is mounted on the second substrate so that an amount of light output from the light source and input to the photo detector through the fifth, the seventh, and the sixth optical waveguides becomes maximum.

What is claimed is:

1. A wavelength variable light source comprising:
a first substrate on which a gain chip and an optical amplifier are formed, the gain chip including a first optical waveguide and the optical amplifier including a second optical waveguide; and
a second substrate on which a wavelength variable block, a third optical waveguide, and a fourth optical waveguide are formed, the wavelength variable block comprising a wavelength variable element, the third optical waveguide being connected to an input end of the wavelength variable block, and the fourth optical waveguide being connected to an output end of the wavelength variable block,
wherein the first optical waveguide and the third optical waveguide are optically coupled to each other and the second optical waveguide and the fourth optical waveguide are optically coupled to each other by mounting the first substrate on the second substrate.

2. The wavelength variable light source according to claim 1, wherein
both the first optical waveguide and the second optical waveguide extend to a first end face of the first substrate, and both the third optical waveguide and the fourth optical waveguide extend to a second end face of the second substrate, and
the first substrate is mounted on the second substrate by joining the first end face and the second end face to each other.

3. The wavelength variable light source according to claim 1, wherein the first optical waveguide and the second optical waveguide are optically coupled to the third optical waveguide and the fourth optical waveguide, respectively, by end face coupling.

4. The wavelength variable light source according to claim 1, wherein the first substrate is an optical semiconductor substrate, and the second substrate is a silicon photonics substrate.

5. The wavelength variable light source according to claim 1, wherein
the first substrate further comprises s a light source, a fifth optical waveguide connected to the light source, a photo detector, and a sixth optical waveguide connected to the photo detector, and
the second substrate comprises a seventh optical waveguide, one end of the seventh optical waveguide being connected to the fifth optical waveguide and another end of the seventh optical waveguide being connected to the sixth optical waveguide in a case where the first substrate is mounted on the second substrate.

6. The wavelength variable light source according to claim 5, wherein the seventh optical waveguide is formed in an area of the second substrate outside an area thereof where the wavelength variable block is formed.

7. The wavelength variable light source according to claim 5, wherein the light source comprises a semiconductor laser.

8. The wavelength variable light source according to claim 5, wherein the photo detector comprises a semiconductor optical amplifier.

9. The wavelength variable light source according to claim 5, wherein the first substrate is mounted on the second substrate so that an amount of light output from the light source and input to the photo detector through the fifth, the seventh, and the sixth optical waveguides becomes maximum.
